(19) United States
(12) Patent Application Publication
(10) Pub. No.: US 2008/0305640 A1
(43) Pub. Date: Dec. 11, 2008

(54) METHOD FOR PREPARING TRENCH POWER TRANSISTORS

(75) Inventors: Ta Ching Chang, Hsinchu City (TW); Meng Hung Chen, Taoyuan City (TW); Wu Hsiung Chen, Hsinchu City (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., Hsinchu (TW)

(21) Appl. No.: 11/843,971

(22) Filed: Aug. 23, 2007

(30) Foreign Application Priority Data
Jun. 7, 2007 (TW) 096120459

(51) Int. Cl. H01L 21/311

(52) U.S. Cl. 438/702; 257/E27.091

(57) ABSTRACT

A method for preparing a trench power transistor comprises the steps of forming a mask layer having a plurality of openings on a semiconductor substrate, removing a portion of the semiconductor substrate under the openings to form a plurality of trenches in the semiconductor substrate in an array manner, coating a photoresist layer covering the surface of the mask layer, patterning the photoresist layer, and removing a portion of the mask layer not covered by the photoresist layer to form a mask block exposing a portion of the semiconductor substrate in the array region.

### BACKGROUND OF THE INVENTION

(A) Field of the Invention

The present invention relates to a method for preparing a trench power transistor, and more particularly, to a method for preparing a trench power transistor by using a single etching mask for patterning two patterns including an array region and trenches.

(B) Description of the Related Art

Metal-Oxide-Semiconductor (MOS) power transistors have the advantages of power conservation and fast switching, and thus have widely replaced conventional bipolar transistors and are applied to technical fields such as switching power supply and mobile electronic devices.

FIG. 1 to FIG. 6 illustrate a method for preparing a trench structure 10 of a conventional power transistor. The method comprises the steps of forming a silicon oxide layer 14 on a silicon substrate 12 including an N⁺-type silicon layer 12A and an N⁻-type silicon layer 12B, coating a photoresist layer 16 on the silicon oxide layer 14 using the photolithography process and performing a wet etching process using an etching solution containing buffered hydrofluoric acid to remove a portion of the silicon oxide layer 14 not covered by the photoresist layer 16 to form a silicon oxide block 14′ for patterning an array region 18, as shown in FIG. 2.

Referring to FIG. 3, after the photoresist layer 16 has been removed, a dielectric layer 20 is formed on the array region 18 and the silicon oxide block 14′ by a deposition process. The method for preparing the dielectric layer 20 comprises the steps of depositing a Tetraethoxysilane (TEOS) layer, annealing the TEOS layer at a temperature of 850° C. for 15 minutes, forming a photoresist layer 22 with a plurality of openings 24 on the dielectric layer 20 by the photolithography process and performing an etching process to remove a portion of the dielectric layer 20 under the openings 24 down to the surface of the N⁻-type silicon layer 12B, as shown in FIG. 4.

Referring to FIG. 5, after the photoresist layer 22 has been removed, performing an etching process using the dielectric layer 20 as the etching mask to remove a portion of the N⁻-type silicon layer 12B not covered by the dielectric layer 20 to a predetermined depth to form a plurality of trenches 26 within the N⁻-type silicon layer 12B. Subsequently, the dielectric layer 20 is removed to complete the trench structure 10, as shown in FIG. 6. However, the silicon oxide block 14′ undergoes a wet etching process to remove the dielectric layer 20 and the width and thickness of the silicon oxide block 14′ are reduced. Therefore, additional width is required to compensate for the width reduction during the wet etching process, which obviously increases the process control difficulty.

### SUMMARY OF THE INVENTION

One aspect of the present invention provides a method for preparing a trench power transistor, wherein a single etching mask is used to pattern an array region and trenches.

A method for preparing a trench power transistor according to this aspect of the present invention comprises the steps of forming a first mask with at least one opening on a silicon substrate, performing a first etching process to remove a portion of the substrate under the opening to form at least one trench in the substrate, forming a second mask covering a portion of the first mask and performing a second etching process to remove a portion of the first mask not covered by the second mask, wherein the remaining first mask serves to pattern an array region.

Another aspect of the present invention provides a method for preparing a trench power transistor, comprising the steps of forming a mask layer with a plurality of openings on a semiconductor substrate, removing a portion of the semiconductor substrate under the openings to form a plurality of trenches in the semiconductor substrate in an array manner, coating a photoresist layer covering the surface of the mask layer, performing a photolithographic process to pattern the photoresist layer and removing a portion of the mask layer not covered by the photoresist layer to form a silicon oxide block patterning the array region and exposing a portion of the semiconductor substrate in the array region.

The prior art must use two layers to create two patterns. In contrast, the present invention first uses the mask layer to pattern the trenches, and then modifies the shape of the mask layer to pattern the array region. Consequently, the present invention uses a single layer to pattern the array region and the trenches.

### BRIEF DESCRIPTION OF THE DRAWINGS

The objectives and advantages of the present invention will become apparent upon reading the following description and upon reference to the accompanying drawings in which:

FIG. 1 to FIG. 6 illustrate a method for preparing a trench structure of a conventional power transistor; and

FIG. 7 to FIG. 13 illustrate the method for preparing a trench power transistor according to one embodiment of the present invention

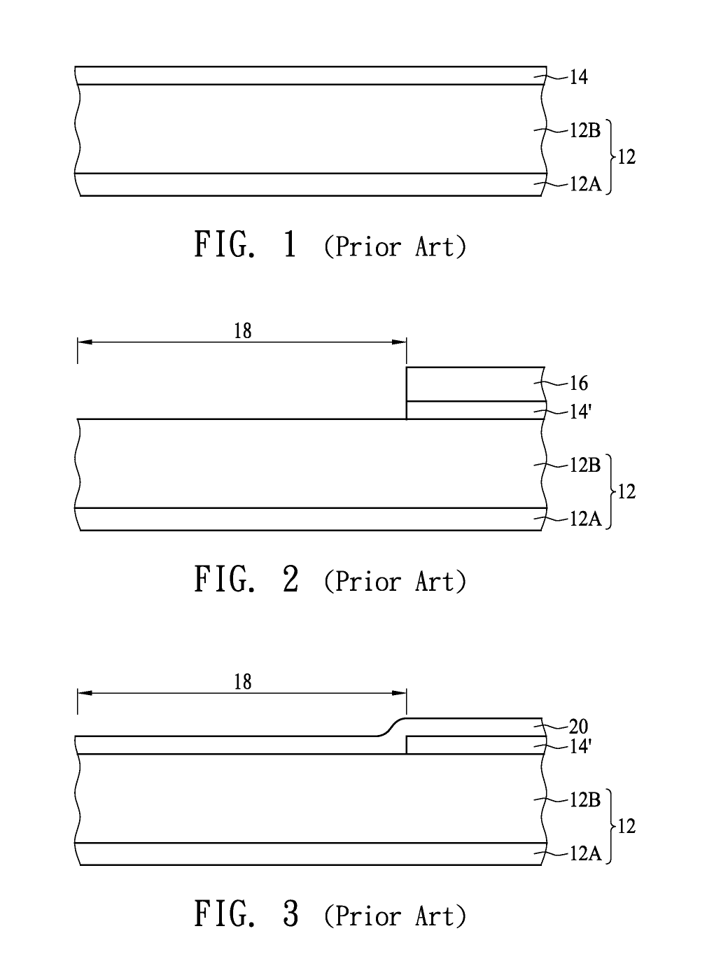

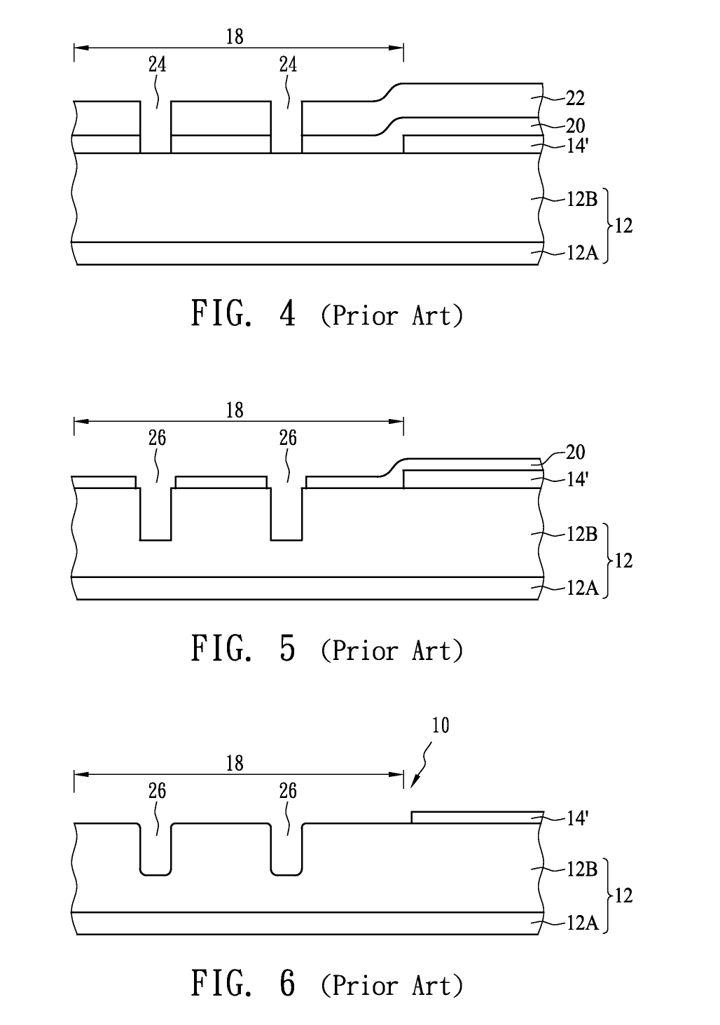

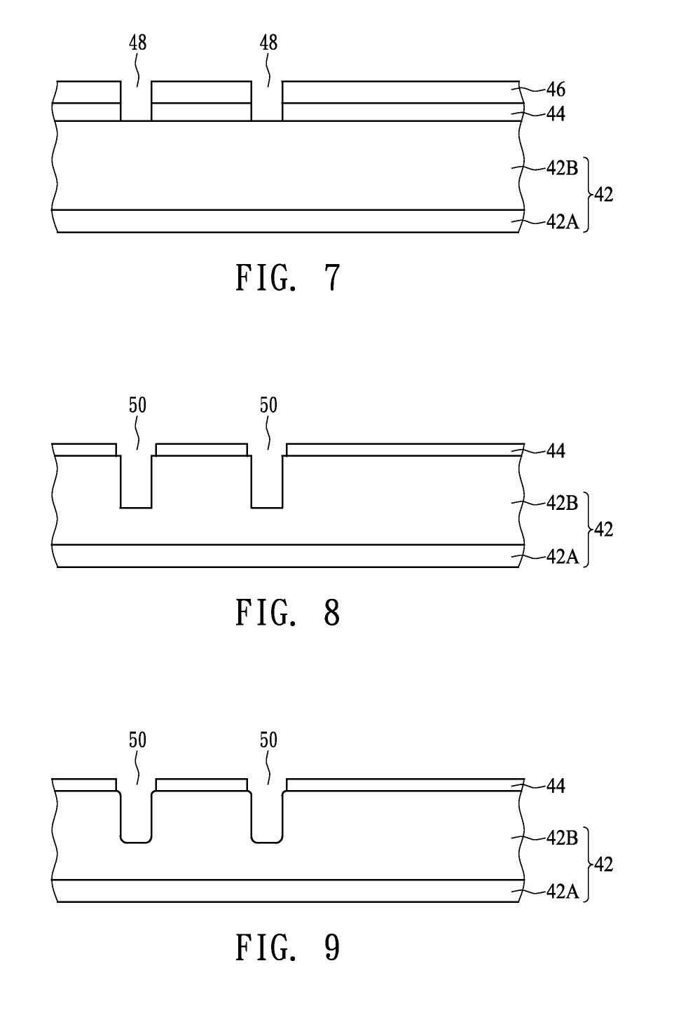

### DETAILED DESCRIPTION OF THE INVENTION

FIG. 7 to FIG. 13 illustrate the method for preparing a trench power transistor 40 according to one embodiment of the present invention. The method forms a dielectric layer on a semiconductor substrate 42 including an N⁺-type silicon layer 42A and an N⁻-type silicon layer 42B, for example, using a thermal oxidation process to form a silicon oxide layer with a thickness of approximately 6,000 angstroms. Subsequently, a trench photoresist layer 46 with a plurality of openings 48 is formed on the silicon oxide layer by photolithographic process, and an etching process is performed to remove a portion of the silicon oxide layer under the openings 48 down to the surface of the N⁻-type silicon layer 42B to form a mask layer 44.

Referring to FIG. 8, after the trench photoresist layer 46 has been removed, a dry etching process is performed using the mask layer 44 as the first etching mask to remove a portion of the N⁻-type silicon layer 42B not covered by the mask layer 44 to a predetermined depth so as to form a plurality of trenches 50 in the N⁻-type silicon layer 42B. A thermal oxidation process is then performed to round off the corners of the trenches 50, i.e., eliminating sharp edges to prevent electronic discharge at the tip of the angle on the trench power transistor 40, as shown in FIG. 9.

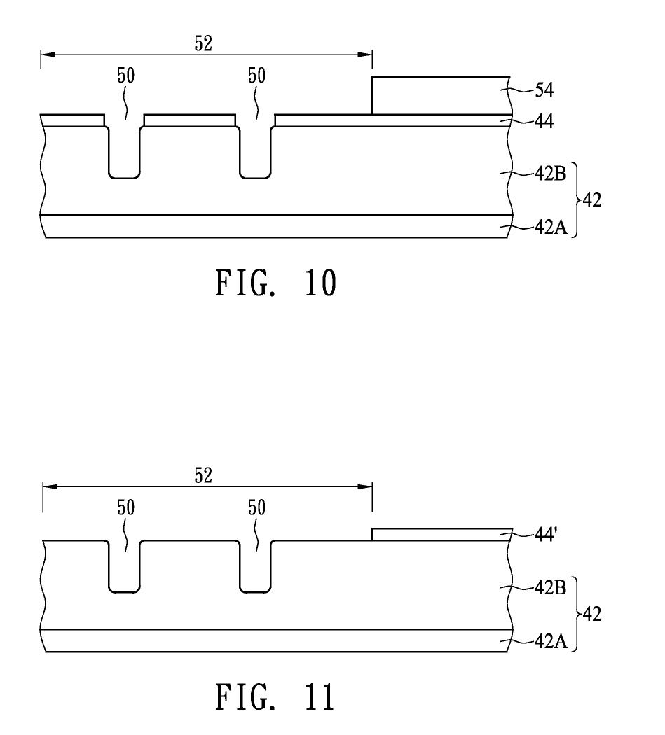

Referring to FIG. 10, an active-area photoresist layer 54 is formed to cover the surface of the mask layer 44, the molecular structure of a portion of the active-area photoresist layer 54 in an array region 52 is modified by the exposure process, and the other portion of the active-area photoresist layer 54 covers the mask layer 44. Subsequently, a wet etching process is performed using the active-area photoresist layer 54 as a second etching mask to remove a portion of the mask layer 44 not covered by the active-area photoresist layer 54 to form a mask block 44′, wherein the mask block 44′ patterns the array region 52 and exposes the semiconductor substrate 42 in the array region 52, as shown in FIG. 11. In particular, the wet etching process uses the etching solution containing hydrofluoric acid, which substantially etches only the silicon oxide (mask layer 44) and not the mono-crystalline silicon (N⁻-type silicon layer 42B).

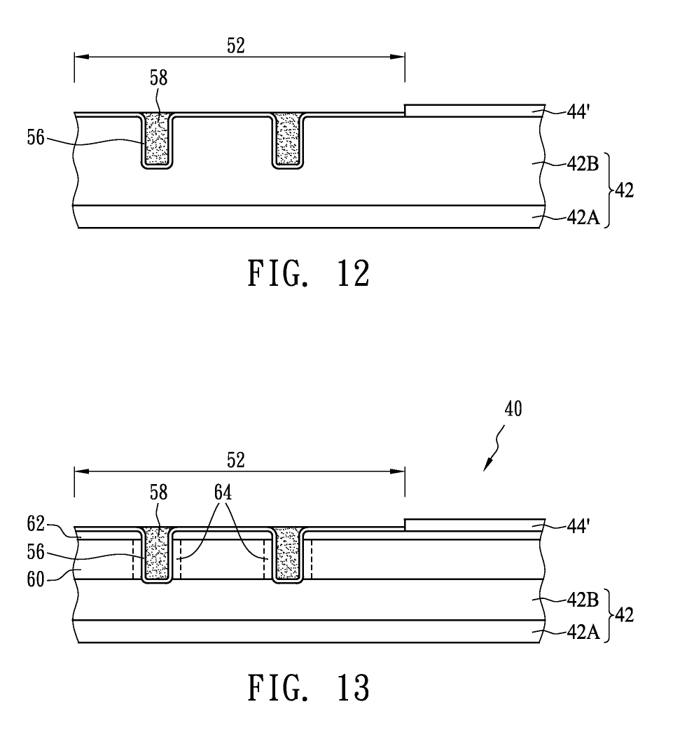

Referring to FIG. 12, a thermal oxidation process is performed to form a gate oxide layer 56 on the inner walls of the trenches 50, and a polysilicon block 58 is then formed to fill the trenches 50. Subsequently, a doping process is performed to form a P-type doped region 60 in the N⁻-type silicon layer 42B, and another doping process is then performed to form an N⁺-type doped region 62 on the P-type doped region 58 to complete the trench power transistor 40, as shown in FIG. 13. In particular, the polysilicon block 58 serves as a gate, the semiconductor substrate 42 serves as a drain, and the N⁺-type doped region 62 serves as a source. The carrier channel 64 of the trench power transistor 40 is deposed within the P-type doped region 60 between the N⁻-type silicon layer 42B and N⁺-type doped region 62, and near to the sidewall of the trenches 50.

It is necessary for the prior art to use the silicon oxide layer 14 to pattern the array region 18, and to use the dielectric layer 20 to pattern the trenches 26, i.e. the prior art requires two layers to pattern two patterns. In contrast, the present invention uses the mask layer 44 to pattern the trenches 50, and modifies the shape of the mask layer 44 to form the mask block 44′ for patterning the array region 52, i.e. the present invention uses only a single layer to create two patterns (the array region 52 and the trenches 50). Consequently, the deposition and annealing process for forming the dielectric layer 20 according to the prior art can be omitted.

Furthermore, the prior art patterns the array region 18 using the silicon oxide block 14′. However, the silicon oxide block 14′ undergoes the subsequent wet etching process for removing the dielectric layer 20 and will be partially etched to reduce the width; therefore, additional width is necessary to compensate for the reduced width, which significantly increases the difficulty of process control. In contrast, according to the present invention, after patterning the mask block 44′ of the array region 18, the mask block 44′ does not experience any wet etching processes that will reduce its width in the subsequent processes. As the width remains constant, the process control is easier.

The above-described embodiments of the present invention are intended to be illustrative only. Numerous alternative embodiments may be devised by those skilled in the art without departing from the scope of the following claims.

What is claimed is:

1. A method for preparing a trench power transistor, comprising the steps of:
forming a first mask having at least one opening on a substrate;
performing a first etching process to remove a portion of the semiconductor under the opening to form at least one trench in the substrate;
forming a second mask covering a portion of the first mask; and
performing a second etching process to remove a portion of the first mask not covered by the second mask to form a mask block for patterning an array region.

2. The method for preparing a trench power transistor of claim 1, wherein the step of forming a first mask having at least one opening on a substrate includes:
forming a dielectric layer on the substrate;
forming a photoresist layer covering a portion of the dielectric layer; and
removing a portion of the dielectric layer not covered by the photoresist layer to form the first mask.

3. The method for preparing a trench power transistor of claim 1, wherein the first mask includes silicon oxide.

4. The method for preparing a trench power transistor of claim 1, wherein the first etching process is a dry etching process.

5. The method for preparing a trench power transistor of claim 1, wherein the step of forming a second mask covering a portion of the first mask includes:
coating a photoresist layer covering the surface of the first mask; and
patterning the photoresist layer by exposing and developing processes to form the second mask.

6. The method for preparing a trench power transistor of claim 1, wherein the second mask includes photoresist.

7. The method for preparing a trench power transistor of claim 6, wherein the second etching process is a wet etching process.

8. The method for preparing a trench power transistor of claim 7, wherein the wet etching process uses an etchant including hydrofluoric acid.

9. The method for preparing a trench power transistor of claim 1, wherein the substrate includes an N⁺-type silicon layer and an N⁻-type silicon layer positioned on the N⁺-type silicon layer, and the trench is positioned in the N⁻-type silicon layer.

10. The method for preparing a trench power transistor of claim 1, further comprising the steps of:
forming a gate oxide layer on an inner wall of the trench;
forming a conductive block in the trench; and
forming a doped region in the substrate at a side of the trench.

11. The method for preparing a trench power transistor of claim 10, wherein the conductive block includes polysilicon.

12. The method for preparing a trench power transistor of claim 1, further comprising a step of performing a thermal treating process to round off a corner of the trench.

13. A method for preparing a trench power transistor, comprising the steps of:
forming a mask layer having a plurality of openings on a semiconductor substrate;
removing a portion of the semiconductor substrate under the openings to form a plurality of trenches in the semiconductor substrate in an array manner;
coating an active-area photoresist layer covering the surface of the mask layer;
patterning the active-area photoresist layer to cover a portion of the mask layer; and
performing a wet etch process to remove a portion of the mask layer not covered by the active-area photoresist layer to form a mask block exposing a portion of the semiconductor substrate in an array region.

14. The method for preparing a trench power transistor of claim 13, wherein the step of forming a mask layer having a plurality of openings on a semiconductor substrate includes:
forming a silicon oxide layer on the semiconductor substrate;
forming a trench photoresist layer covering a portion of the silicon oxide layer; and
removing a portion of the silicon oxide layer not covered by the trench photoresist layer.

15. The method for preparing a trench power transistor of claim 13, wherein the step of removing a portion of the semiconductor substrate is performing a dry etching process.

16. The method for preparing a trench power transistor of claim 13, wherein the wet etching process uses an etchant including hydrofluoric acid.

17. The method for preparing a trench power transistor of claim 13, wherein the semiconductor substrate includes an N⁺-type silicon layer and an N⁻-type silicon layer positioned on the N⁺-type silicon layer, and the trenches are positioned in the N⁻-type silicon layer.

18. The method for preparing a trench power transistor of claim 13, further comprising the steps of:
forming a gate oxide layer on an inner wall of the trenches;
forming a conductive block in the trenches; and
forming a doped region in the semiconductor substrate at one side of the trenches.

19. The method for preparing a trench power transistor of claim 18, wherein the conductive block includes polysilicon.

20. The method for preparing a trench power transistor of claim 13, further comprising a step of performing a thermal treating process to round off a corner of the trench.
